(19) United States
(12) Patent Application Publication
(10) Pub. No.: US 2026/0227446 A1
(43) Pub. Date: Aug. 6, 2026

(54) CHARGING AND DISCHARGING APPARATUS, CONTROLLING METHOD OF THE SAME, AND CHARGING AND DISCHARGING SYSTEM INCLUDING THE SAME

(71) Applicant: SK On Co., Ltd., Seoul (KR)

(72) Inventors: Yu Gyung KIM, Daejeon (KR); Jung Hak YOON, Daejeon (KR); Byung Wook KIM, Daejeon (KR); Woo Seop KIM, Daejeon (KR); Jung Uk KIM, Daejeon (KR); Kwae Ha KIM, Daejeon (KR); Ji Won HONG, Daejeon (KR)

(21) Appl. No.: 19/460,322

(22) Filed: Jan. 27, 2026

(30) Foreign Application Priority Data
Jan. 31, 2025 (KR) 10-2025-0012455

(51) Int. Cl. G01R 31/374; G01R 31/36; G01R 31/387; G01R 31/396; H01M 10/42; H01M 10/44; H01M 10/48

(52) U.S. Cl. CPC G01R 31/374; G01R 31/387; G01R 31/396; H01M 10/425; H01M 10/441; H01M 10/482; H01M 10/486; G01R 31/3644; H01M 2010/4278

(57) ABSTRACT

A charging and discharging apparatus, a controlling method thereof, and a charging and discharging system including the same are provided. The charging and discharging apparatus may include a charging and discharge channel unit electrically connected to a plurality of battery cells, a plurality of jigs configured to support the plurality of battery cells; a temperature sensor unit configured to measure the temperature of an area adjacent to the plurality of battery cells, and a control unit configured to control the temperature sensor unit, charging or discharging the plurality of battery cells through the charging and discharging channel unit, and configured to measure the charge capacity of each battery cell, wherein the control unit is configured to calculate a modified charge capacity of each battery cell based on the temperature measured by the temperature sensor unit and a calculated charge capacity of each battery cell.

This application claims priority under 35 U.S.C. § 119a to Korean Patent Application No. 10-2025-0012455 filed on Jan. 31, 2025 in the Ministry of Intellectual Property of the Republic of Korea, the entire contents of which are incorporated by reference herein.

### TECHNICAL FIELD

This disclosure relates to a charging and discharging apparatus, a controlling method thereof, and a charging and discharging system including the same. Specifically, it relates to a charging and discharging apparatus, a controlling method thereof, and a charging and discharging system including the same, which improve the manufacturing efficiency of battery cells.

### BACKGROUND

A charging and discharging apparatus performs the function of imparting characteristics to a battery cell by repeating a charging and discharging process several times during the production process of a secondary battery or battery cell, enabling the first assembled battery cell to store electrical energy.

Battery cells charged and discharged in the apparatus may exhibit variations in charge capacity depending on their position within the apparatus. This occurs because the environment (e.g., temperature) experienced by the battery cells differs based on their location and the position of the charging and discharging channel unit. Specifically, conventional charging and discharging apparatus calculate the charge capacity or electrical capacity of a battery cell being charged through a charging and discharging channel unit using a single calibration formula. Consequently, the calculated charge capacity for battery cells charged or discharged at different positions may differ from the actual measured capacity. Therefore, a calibration method capable of more accurately reflecting the charge capacity of the battery cell is required.

Therefore, firstly, according to one aspect of the present disclosure, an object is to improve the manufacturing efficiency of battery cells.

Secondly, according to another aspect of the present disclosure, an object is to reduce the defect rate of battery cells.

Thirdly, according to another aspect of the present disclosure, an object is to improve the quality of the battery cell.

Meanwhile, the battery cell of the present disclosure can be widely applied in green technology fields such as electric vehicles, battery charging stations, and solar power generation and wind power generation utilizing batteries. Furthermore, the battery cell of the present disclosure can be used in eco-friendly electric vehicles and hybrid vehicles to prevent climate change by suppressing air pollution and greenhouse gas emissions.

### SUMMARY

A charging and discharging apparatus according to an aspect of this disclosure may comprise: a charging and discharge channel unit electrically connected to a plurality of battery cells; a plurality of jigs configured to support the plurality of battery cells; a temperature sensor unit positioned on a side of the plurality of jigs, the temperature sensor unit configured to measure the temperature of an area adjacent to the plurality of battery cells; and a control unit configured to control the temperature sensor unit, charging or discharging the plurality of battery cells through the charging and discharging channel unit, the control unit configured to measure the charge capacity of each battery cell; wherein the control unit may be configured to calculate a modified charge capacity of each battery cell based on the temperature measured by the temperature sensor unit and a calculated charge capacity of each battery cell during charging or discharging each battery cell through the charging and discharging channel unit.

In an aspect, the charging and discharging channel unit may include a plurality of charging and discharging channels that charge a plurality of battery groups respectively, each group including a predetermined number of the plurality of battery cells.

In an aspect, the temperature sensor unit may include a plurality of temperature sensors configured to measure the temperature of an area to which each battery group belongs.

In an aspect, the control unit may be configured to calculate an average charge capacity B of any one battery group among the plurality of battery groups and an average charge capacity A of the remaining battery groups excluding the any one battery group, based on the temperature of the area to which each battery group belongs, measured through the plurality of temperature sensors, during charging or discharging each battery group through the plurality of charging and discharging channels.

In an aspect, the control unit may be configured to calculate the modified charge capacity of a battery cell among the battery groups using the following equation 1.

$$ACC = MCC \times \{ 1 + ( A - B ) / B \} \qquad [ Equation 1 ]$$

where ACC represents the modified charge capacity of the battery cell, MCC represents the calculated charge capacity of the battery cell, B represents the average charge capacity of any one battery group among the plurality of battery groups, and A represent the average charge capacity of the remaining battery groups excluding the any one battery group.

In an aspect, the temperature of the area to which each battery group belongs may be the average temperature in a predetermined measurement section during charging or discharging of the plurality of battery cells.

A charging and discharging system according to another aspect of this disclosure may comprise: a charging and discharge channel unit electrically connected to a plurality of battery cells; a plurality of jigs configure to support the plurality of battery cells; a temperature sensor unit positioned on a side of the plurality of jigs, the temperature sensor unit configured to measure the temperature of an area adjacent to the plurality of battery cells; a control unit configured to control the temperature sensor unit, charging or discharging the plurality of battery cells through the charging and discharging channel unit, the control unit configured to measure the charge capacity of each battery cell; and a server configured to communicate with the control unit; wherein the control unit may be configured to calculate a modified charge capacity of each battery cell based on the temperature measured by the temperature sensor unit and a calculated charge capacity of each battery cell during charging or discharging each battery cell through the charging and discharging channel unit, the control unit configured to transmit the modified charge capacity of each battery to the server.

A controlling method of a charging and discharging apparatus, including a charging and discharge channel unit electrically connected to a plurality of battery cells and a plurality of jigs supporting the plurality of battery cells, according to another aspect of this disclosure may comprise: a step of charging or discharging each battery cell through the charging and discharging channel unit; a step of calculating the charge capacity of each battery cell through the charging and discharging channel unit based on the temperature measured by a temperature sensor unit located on a side of the plurality of jigs, the temperature sensor unit configured to measure the temperature of an area adjacent to the plurality of battery cells; and a step of modifying the charge capacity of each battery cell based on the calculated charge capacity of each battery cell through the charging and discharging channel unit.

In another aspect, the controlling method may further comprise: a step of placing the plurality of battery cells on the plurality of jigs prior to the step of charging or discharging each battery cell.

In another aspect, the controlling method may further comprise: a step of transmitting the modified charge capacity of each battery cell to a server configured to communicate with the charging and discharging apparatus after the step of modifying the charge capacity of each battery cell.

In another aspect, the step of modifying the charge capacity of each battery cell may include a step of calculating an average charge capacity B of any one battery group among the plurality of battery groups and an average charge capacity A of the remaining battery groups excluding the any one battery group, based on the temperature of the area to which each battery group belongs, measured through the plurality of temperature sensors, during charging or discharging each battery group through the plurality of charging and discharging channels.

In another aspect, the modified charge capacity of a battery cell among the battery groups may be calculated using the following equation 2.

$$ACC = MCC \times \{ 1 + ( A - B ) / B \} \qquad [ Equation 2 ]$$

where ACC represents the modified charge capacity of the battery cell, MCC represents the calculated charge capacity of the battery cell, B represents the average charge capacity of any one battery group among the plurality of battery groups, and A represent the average charge capacity of the remaining battery groups excluding the any one battery group.

In another aspect, the temperature of the area to which each battery group belongs may be the average temperature in a predetermined measurement section during charging or discharging of the plurality of battery cells.

First, according to an aspect of the present disclosure, the manufacturing efficiency of battery cells may be improved.

Second, according to another aspect of the present disclosure, the defect rate of the battery cells may be reduced.

Third, according to yet another aspect of the present disclosure, the quality of the battery cell may be improved.

### BRIEF DESCRIPTION OF THE DRAWINGS

FIG. 1 illustrates an example of a charging and discharging apparatus according to the present disclosure viewed from the front.

FIG. 2 schematically illustrates an example of a stage unit according to the present disclosure as viewed from the side.

FIG. 3 shows a block diagram for controlling the charging and discharging apparatus according to the present disclosure.

FIG. 4 illustrates an example of a charging and discharging system according to the present disclosure.

FIG. 5 is a flowchart illustrating a control method of the charging and discharging apparatus according to the present disclosure.

### DETAILED DESCRIPTION

The following describes the present disclosure in detail with reference to the accompanying drawings. However, this is merely illustrative, and the present disclosure is not limited to the specific aspects described herein.

In this disclosure, the terms “battery,” “secondary battery,” and “cell” all refer to the same rechargeable battery cell.

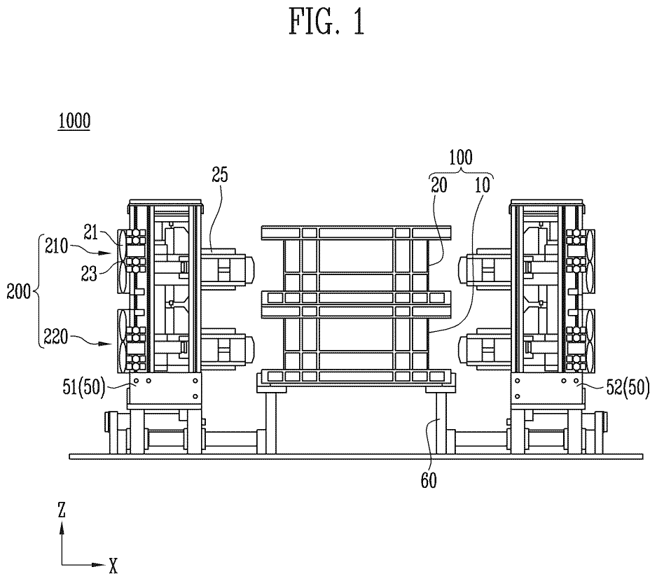

FIG. 1 illustrates an example of a charging and discharging apparatus according to the present disclosure viewed from the front.

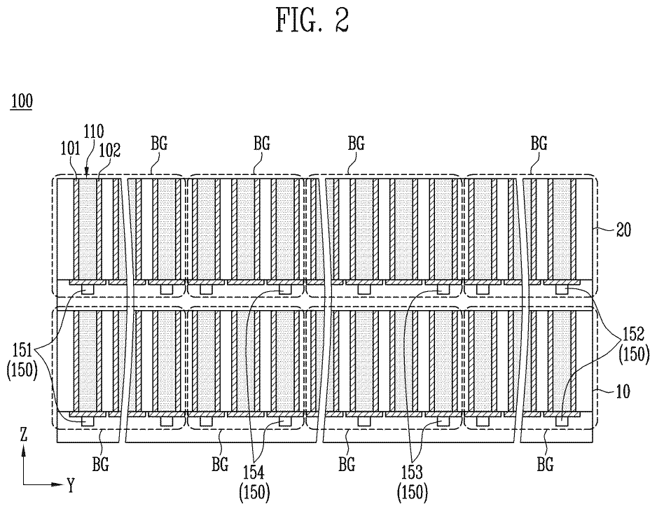

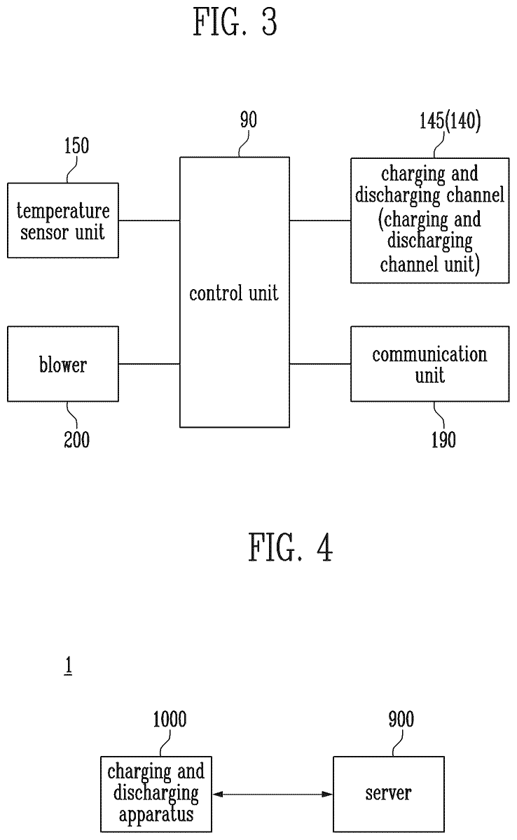

The charging and discharging apparatus 1000 according to the present disclosure may include a stage 100 for accommodating a plurality of battery cells 110, referring to FIG. 2, and a charging and discharging channel unit 140, referring to FIG. 3, electrically connected to charge and discharge each of the plurality of battery cells 110.

Furthermore, the charging and discharging apparatus 1000 may include a blower 200 that blows external air toward the plurality of battery cells 110 while being positioned between the plurality of battery cells 110.

The charging and discharging apparatus 1000 may refer to a battery cell charging and discharging apparatus used to charge and discharge battery cells in an online or offline process.

In this disclosure, the type of the plurality of battery cells 110 is described as an example using a pouch type, but is not limited thereto, the type of the plurality of battery cells 110 may also be a cylindrical or prismatic type.

The stage 100 may accommodate the plurality of battery cells 110. Referring to FIG. 1, for example, the stage 100 may be configured as two stacks along the height direction (Z-direction) of the charging and discharging apparatus 1000. That is, the stage 100 may include a first stage 10 and a second stage 20 each accommodating a plurality of battery cells 110, wherein the second stage 20 may be disposed on top of the first stage 10.

However, this is merely one example, and the number of stacked stages of the stage 100 may be varied.

The stage 100 may be supported by the support portion 60.

The blower 200 may draw in external air and supply it toward the plurality of battery cells 110. The blower 200 may be arranged along the width direction (X-direction) of the charging and discharging apparatus 1000, with the stage 100 positioned between them.

The blower 200 may draw in external air and supply it toward each stage of the stage 100. For example, referring to FIG. 1, the blower 200 may be provided in a plurality, and the plurality of blowers 200 may include a first blower 210 that supplies external air toward the first stage 10, and a second blower 220 that supplies external air toward the second stage 20.

The first blower 210 may be provided in a plurality, and the plurality of first blowers 210 may be arranged parallel to the first stage 10 along the front-rear direction of the charging and discharging apparatus 1000.

Similarly, the second blower 220 may be provided in a plurality, and the plurality of second blowers 220 may be arranged parallel to the second stage 20 along the front-rear direction of the charging and discharging apparatus 1000.

The blower 200 may include a motor (not shown) for generating rotational force, a blowing fan 21 connected to the rotational shaft of the motor, and a blowing duct 25 for conveying air sucked in through the blowing fan 21 toward the plurality of battery cells 110.

Furthermore, the center portion of the blowing fan 21 may be coupled to the rotational shaft of the motor. The control unit 90, described later, may control the airflow volume of the blower 200. The airflow may be defined as the volume of air per unit time moving from any one blower 200 through the blowing fan 21 toward the stage 100. If the blower 200 includes a blowing fan 21, the airflow will be proportional to the rotational speed of the blowing fan 21.

Meanwhile, the charging and discharging apparatus 1000 according to this disclosure may further include a blowing frame 50 that supports the blower 200. Since the blower 200 is positioned with the stage 100 in between, the blowing frame 50 may include a first blowing frame 51 positioned on the left side (L direction) of the stage 100 and a second blowing frame 52 positioned on the right side (R direction) of the stage 100.

FIG. 2 schematically illustrates an example of a stage unit according to the present disclosure as viewed from the side.

As described above, the stage 100 may include a plurality of stages 10, 20 stacked along the height direction of the charging and discharging apparatus 1000. Although FIG. 2 shows a two-stage configuration, this is merely an example, and the number of stages is not limited to two.

The stage 100 may include jigs 101, 102 for accommodating a plurality of battery groups BG, each formed by grouping adjacent battery cells 110 from the plurality of battery cells 110, and a temperature sensor unit 150 for measuring the temperature of an area adjacent to the plurality of battery groups BG.

In another example, the plurality of battery groups BG may each be loaded onto a tray (not shown) and accommodated in the stage 100. The jigs 101, 102 may be electrically connected to the battery groups BG accommodated on the tray.

The temperature sensor unit 150 may be provided in a plurality. For example, the plurality of temperature sensor units 150 may include a first temperature sensor 151, a second temperature sensor 152, a third temperature sensor 153, and a fourth temperature sensor 154 arranged corresponding to the plurality of battery groups BG.

The plurality of battery cells 110 may be grouped into a predetermined number of adjacent battery cells 110 to form a plurality of battery groups BG. The plurality of battery groups BG may each be accommodated in one of the plurality of stages 10, 20.

For example, referring to FIG. 2, the first stage 10 and the second stage 20 can accommodate the plurality of battery groups BG.

The stage 100 may further include jigs 101, 102 that detachably support the plurality of battery cells 110 respectively. That is, one battery cell 110 may be placed between the jigs 101, 102.

Meanwhile, the charging and discharging apparatus 1000 according to this disclosure may further include a temperature sensor unit 150 positioned on one side of the plurality of jigs 101, 102 to measure the temperature of the area adjacent to the plurality of battery cells 110.

For example, the temperature sensor unit 150 may include a plurality of temperature sensors 151, 152, 153, 154. Referring to FIG. 2, each stage 10, 20 includes four battery groups BG, and the plurality of temperature sensors 151, 152, 153, 154 may be arranged corresponding to each battery group BG of each stage 10, 20. Therefore, each battery group BG may correspond to at least one temperature sensor.

FIG. 3 shows a block diagram for controlling the charging and discharging apparatus according to the present disclosure.

Referring to FIGS. 2 and 3, the charging and discharging apparatus 1000 according to the present disclosure includes a charging and discharging channel unit 140 electrically connected to a plurality of battery cells 110, a plurality of jigs 101, 102 supporting the plurality of battery cells 110, a temperature sensor unit 150 positioned on one side of the plurality of jigs 101, 102 to measure the temperature of the area adjacent to the plurality of battery cells 110, and a control unit 90 that controls the temperature sensor unit 150, charges or discharges the plurality of battery cells 110 through the charging and discharging channel unit 140, and calculates the charge capacity of each battery cell 110.

Furthermore, the control unit 90 can calculate a modified charge capacity of each battery cell 110 based on the temperature measured by the temperature sensor unit 150 and the calculated or estimated charge capacity of each battery cell 110 during charging or discharging through the charging and discharging channel unit 140.

The control unit 90 can charge and discharge the plurality of battery cells 110 accommodated in the stage 100 through the charging and discharging channel unit 140.

The charging and discharging channel unit 140 may include a plurality of charging and discharging channels 145 for charging a plurality of battery groups BG grouped by a predetermined number from the plurality of battery cells 110.

The control unit 90 can charge and discharge the plurality of battery groups BG electrically connected to the plurality of charging and discharging channels 145 through the plurality of charging and discharging channels 145.

Furthermore, the control unit 90 can determine whether charging and discharging of the plurality of battery cells 110 has been completed through the charging and discharging channel unit 140, and can ascertain the charge capacity of each of the plurality of battery cells 110 through the charging and discharging channel unit 140.

The charge capacity refers to the electrical capacity of any one battery cell 110 when its state of charge SOC is 100%. The control unit 90 can determine the charge capacity of any one battery cell 110 during its charging or discharging through any one charging and discharging channel 145 connected to that battery cell 110.

Meanwhile, when charging or discharging the plurality of battery cells 110, heat generation may occur in the plurality of battery cells 110. Therefore, for thermal management of the charging and discharging apparatus 1000, the control unit 90 can control the blower 200.

However, during charging and discharging, the temperature of the plurality of battery cells 110 may vary depending on the location of the plurality of battery cells 110 or the location of the plurality of battery groups BG.

That is, heat dissipation from battery cells 110 located on both sides of the charging and discharging apparatus 1000 may be greater than heat dissipation from battery cells 110 located in the central region. That is, the temperature of battery cells 110 in battery groups BG located closer to both sides of the charging and discharging apparatus 1000 may be lower than the temperature of battery cells 110 located in the central region.

Since the charge capacity of the battery cell 110 is also related to temperature data, the charge capacity of the battery cell 110 in the battery group BG located closer to both sides of the charging and discharging apparatus 1000 may be calculated lower than the charge capacity of the battery cell 110 located in the central region.

Consequently, the charge capacity of battery cells 110 located closer to both sides of the charging and discharging apparatus 1000 is often calculated as lower than the reference value and thus judged as defective. However, the actual charge capacity of these battery cells 110 judged as defective often satisfies the reference value.

The control method for the charging and discharging apparatus according to this disclosure involves correcting the charge capacity of the plurality of battery cells 110 calculated by the control unit 90 to reflect the actual charge capacity, taking into account the positions of the plurality of battery cells 110 being charged and discharged in the charging and discharging apparatus 1000.

Since the plurality of battery cells 110 are divided into multiple battery groups BG and charging and discharging occurs through a charging and discharging channel 145 corresponding to each battery group BG, the charging and discharging apparatus 1000 can modify or calibrate the charge capacity of the battery cells 110 included in the battery group BG corresponding to any one charging and discharging channel 145 through that one charging and discharging channel 145, or modify or calibrate the calibration capacity of individual battery cells 110.

More specifically, during charging or discharging each battery group BG through the plurality of charging and discharging channels 145, based on the temperature of the area to which each battery group BG belongs as measured through the plural temperature sensors 151, 152, 153, 154, the control unit 90 can calculate an average charge capacity B of any one battery group among the plurality of battery groups BG and an average charge capacity A of the remaining battery groups excluding the any one battery group.

Here, the temperature of the area to which each battery group BG belongs may be the average temperature during a predetermined measurement section while the plurality of battery cells 110 are charging or discharging.

Based on the average temperature during a predetermined measurement section when the plurality of battery cells 110 are charged or discharged, the charge capacity of the plurality of battery cells 110 can be calculated. Through this, the control unit 90 can calculate the average charge capacity B of any one battery group among the plurality of battery groups BG and the average charge capacity A of the remaining battery groups excluding the any one battery group.

The temperature of the area to which each battery group BG belongs may be the average temperature over the entire charging or discharging time of the plurality of battery cells 110. Alternatively, the temperature of the area to which each battery group BG belongs may be the temperature acquired at a specific point in time via the plurality of temperature sensors 151, 152, 153, 154.

More specifically, the control unit 90 can calculate the modified charge capacity of any battery cell 110 in any one of the battery groups BG using Equation 1.

$$ACC = MCC \times \{ 1 + ( A - B ) / B \} \qquad [ Equation 1 ]$$

where ACC represents the modified charge capacity of the battery cell 110, MCC represents the calculated charge capacity of the battery cell 110, B represents the average charge capacity of any one battery group among the plurality of battery groups BG, and A represent the average charge capacity of the remaining battery groups excluding the any one battery group.

Furthermore, the control unit 90 can control the temperature sensor unit 150. The temperature sensor unit 150 may include a plurality of temperature sensors 151, 152, 153, 154 that measure the temperature of the area where each battery group BG is located. The plurality of temperature sensors 151, 152, 153, 154 are each placed at least one per battery group BG to measure the temperature of the area adjacent to the battery group BG or the temperature of the battery group BG itself.

Furthermore, the control unit 90 can individually control the blower 200 based on the temperatures measured through the temperature sensor unit 150. This is for thermal management of the plurality of battery cells 110 housed within the charging and discharging apparatus 1000.

Furthermore, the control unit 90 may additionally include a communication unit 190 for communicating with other devices (e.g., a server).

Furthermore, the control unit 90 may receive user commands or control an input/output unit (not shown) that displays execution status and results.

That is, the charging and discharging system 1 according to this disclosure comprises a charging and discharging channel unit 140 electrically connected to a plurality of battery cells 110, a plurality of jigs 101, 102 supporting the plurality of battery cells 110, a temperature sensor unit 150 positioned on a side of the plurality of jigs 101, 102 to measure the temperature of an area adjacent to the plurality of battery cells 110, a control unit 90 that controls the temperature sensor unit 150, charging or discharging the plurality of battery cells 110 through the charging and discharging channel unit 140, and measures the charge capacity of each battery cell 110, and a server 900 communicable with the control unit 90, wherein the control unit 90 calculates a modified charge capacity of each battery cell based on the temperature measured by the temperature sensor unit and the calculated charge capacity of each battery cell 110 during charging or discharging of the plurality of battery cells 110 via the charging and discharging channel unit 140, and transmit the modified charge capacity of each battery cell 110 to the server.

FIG. 4 illustrates an example of a charging and discharging system according to the present disclosure.

As described above, the charging and discharging apparatus 1000 according to this disclosure can calculate the charge capacity of the plurality of battery cells 110 accommodated within the charging and discharging apparatus 1000 and undergoing charging and discharging based on the temperature obtained through the temperature sensor unit 150, and modify the calculated charge capacity according to a relationship formula to match the actual charge capacity.

Furthermore, information regarding the modified charge capacity may be stored in a server or management server that stores information about the plurality of battery cells 110.

For this purpose, the charging and discharging system 1 according to the present disclosure may include the charging and discharging apparatus 1000 and a server 900 that communicates with the charging and discharging apparatus 1000 and stores information about the charge capacity of the plurality of battery cells 110 accommodated in the charging and discharging apparatus 1000.

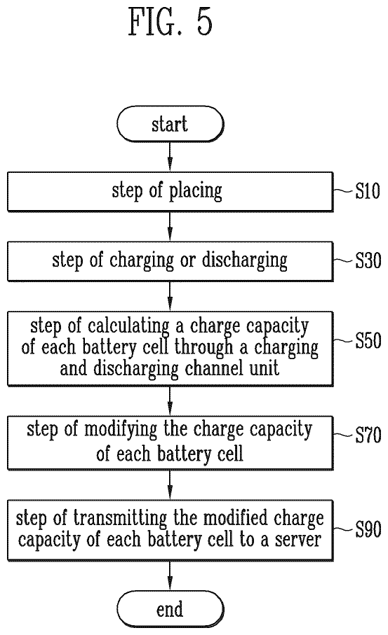

FIG. 5 is a flowchart illustrating a control method of the charging and discharging apparatus according to the present disclosure.

The control method for the charging and discharging apparatus 1000 according to the present disclosure includes: a step S30 of charging or discharging each battery cell 110 through the charging and discharging channel unit 140; a step S50 of calculating the charge capacity of each battery cell 110 through the charging and discharging channel unit 140 based on the temperature measured by the temperature sensor unit 150 located on a side of the plurality of jigs 101, 102 and measuring the temperature of the area adjacent to the plurality of battery cells 110, and a step S70 of modifying the charge capacity of each battery cell 110 based on the calculated charge capacity of each battery cell 110 through the charging and discharging channel unit 140.

In the step S30 of charging or discharging each battery cell 110, the control method of the charging and discharging apparatus 1000 according to this disclosure can fully charge or discharge each battery cell 110 through the charging and discharging channel unit 140.

In contrast, the control method for the charging and discharging apparatus 1000 according to the present disclosure may also charge to a predetermined target charge value or discharge to a predetermined target discharge value through the charging and discharging channel unit 140.

In the step S30 of charging or discharging each battery cell 110, the control method of the charging and discharging apparatus 1000 according to this disclosure can calculate or estimate the charge capacity of the plurality of battery cells 110 based on the temperature of the area to which each battery group BG belongs, measured by the temperature sensor unit 150.

That is, based on the temperature of the area to which each battery group BG belongs, measured by the temperature sensors 151, 152, 153, 154 corresponding to each battery group BG, the control method of the charging and discharging apparatus 1000 according to this disclosure can calculate or estimate the charge capacity of each battery cell 110 or the battery cells 110 included in each battery group BG.

Here, the temperature of the area to which each battery group BG belongs may be the average temperature during a predetermined measurement section during charging or discharging the plurality of battery cells 110.

Alternatively, the temperature of the area to which each battery group BG belongs may be the average temperature over the entire charging or discharging time of the plurality of battery cells 110. Alternatively, the temperature of the area to which each battery group BG belongs may be the temperature acquired at a specific point in time via the plurality of temperature sensors 151, 152, 153, 154.

Subsequently, the control method for the charging and discharging apparatus 1000 according to this disclosure, in the step S70 of modifying the charge capacity of each battery cell 110, when charging or discharging multiple battery groups BG grouped from the plurality of battery cells 110 into a predetermined number of groups through the charging and discharging channel unit 140, based on the temperature of the area to which each battery group BG belongs, measured by a plurality of temperature sensors 151, 152, 153, 154 included in the temperature sensor unit 150, an average charge capacity B of any one battery group among the plurality of battery groups BG and an average charge capacity A of the remaining battery groups excluding the any one battery group can be calculated.

More specifically, in the control method for the charging and discharging apparatus 1000 according to this disclosure, in the step S70 of modifying the charge capacity of each battery cell 110, the modified charge capacity of any battery cell 110 in any one of the battery groups BG can be calculated using the following Equation 2.

$$ACC = MCC \times \{ 1 + ( A - B ) / B \} \qquad [ Equation 2 ]$$

where ACC represents the modified charge capacity of the battery cell, MCC represents the calculated charge capacity of the battery cell, B represents the average charge capacity of any one battery group among the plurality of battery groups, and A represent the average charge capacity of the remaining battery groups excluding the any one battery group.

Additionally, the control method for the charging and discharging apparatus 1000 according to this disclosure may further include a step S10 of placing the plurality of battery cells 110 on the plurality of jigs 101, 102 prior to the step of charging or discharging S30.

Moreover, the control method for the charging and discharging apparatus 1000 according to this disclosure may further include a step S90 of transmitting the modified charge capacity of each battery cell 110 to a server 900 communicating with the charging and discharging apparatus 1000 after the step S70 of modifying the charge capacity of each battery cell 110.

Through this, the charge capacity of the plurality of battery cells 110 charged and discharged by the charging and discharging apparatus 1000 can be updated to the modified charge capacity and managed by the server 900.

The above description is merely an example applying the principles of the present disclosure, and other configurations may be included within the scope of the invention without departing from its scope.

What is claimed is:

1. A charging and discharging apparatus, comprising:
a charging and discharge channel unit electrically connected to a plurality of battery cells;
a plurality of jigs configured to support the plurality of battery cells;
a temperature sensor unit positioned on a side of the plurality of jigs, the temperature sensor unit configured to measure the temperature of an area adjacent to the plurality of battery cells; and
a control unit configured to control the temperature sensor unit, charging or discharging the plurality of battery cells through the charging and discharging channel unit, the control unit configured to measure the charge capacity of each battery cell;
wherein the control unit is configured to calculate a modified charge capacity of each battery cell based on the temperature measured by the temperature sensor unit and a calculated charge capacity of each battery cell during charging or discharging each battery cell through the charging and discharging channel unit.

2. The charging and discharging apparatus according to claim 1, wherein the charging and discharging channel unit includes a plurality of charging and discharging channels that charge a plurality of battery groups respectively, each group including a predetermined number of the plurality of battery cells.

3. The charging and discharging apparatus according to claim 2, wherein the temperature sensor unit includes a plurality of temperature sensors configured to measure the temperature of an area to which each battery group belongs.

4. The charging and discharging apparatus according to claim 3, wherein the control unit configured to calculate an average charge capacity B of any one battery group among the plurality of battery groups and an average charge capacity A of the remaining battery groups excluding the any one battery group, based on the temperature of the area to which each battery group belongs, measured through the plurality of temperature sensors, during charging or discharging each battery group through the plurality of charging and discharging channels.

5. The charging and discharging apparatus according to claim 4, wherein the control unit configured to calculate the modified charge capacity of a battery cell among the battery groups using the following equation 1,
$$ACC = MCC \times \{ 1 + ( A - B ) / B \} \qquad [ Equation 1 ]$$
where ACC represents the modified charge capacity of the battery cell, MCC represents the calculated charge capacity of the battery cell, B represents the average charge capacity of any one battery group among the plurality of battery groups, and A represent the average charge capacity of the remaining battery groups excluding the any one battery group.

6. The charging and discharging apparatus according to claim 4, wherein the temperature of the area to which each battery group belongs is the average temperature in a predetermined measurement section during charging or discharging of the plurality of battery cells.

7. A charging and discharging system, comprising:
a charging and discharge channel unit electrically connected to a plurality of battery cells;
a plurality of jigs configured to support the plurality of battery cells;
a temperature sensor unit positioned on a side of the plurality of jigs, the temperature sensor unit configured to measure the temperature of an area adjacent to the plurality of battery cells;
a control unit configured to control the temperature sensor unit, charging or discharging the plurality of battery cells through the charging and discharging channel unit, and the control unit configured to measure the charge capacity of each battery cell; and
a server configured to communicate with the control unit;
wherein the control unit configured to calculate a modified charge capacity of each battery cell based on the temperature measured by the temperature sensor unit and a calculated charge capacity of each battery cell during charging or discharging each battery cell through the charging and discharging channel unit, the control unit configured to transmit the modified charge capacity of each battery to the server.

8. A controlling method of a charging and discharging apparatus, including a charging and discharge channel unit electrically connected to a plurality of battery cells and a plurality of jigs supporting the plurality of battery cells, comprising:
a step of charging or discharging each battery cell through the charging and discharging channel unit;
a step of calculating the charge capacity of each battery cell through the charging and discharging channel unit based on the temperature measured by a temperature sensor unit located on a side of the plurality of jigs, the temperature sensor unit configured to measure the temperature of an area adjacent to the plurality of battery cells; and
a step of modifying the charge capacity of each battery cell based on the calculated charge capacity of each battery cell through the charging and discharging channel unit.

9. The controlling method of a charging and discharging apparatus according to claim 8, further comprising:
a step of placing the plurality of battery cells on the plurality of jigs prior to the step of charging or discharging each battery cell.

10. The controlling method of a charging and discharging apparatus according to claim 9, further comprising:
a step of transmitting the modified charge capacity of each battery cell to a server configured to communicate with the charging and discharging apparatus after the step of modifying the charge capacity of each battery cell.

11. The controlling method of a charging and discharging apparatus according to claim 8, wherein the step of modifying the charge capacity of each battery cell includes a step of calculating an average charge capacity B of any one battery group among the plurality of battery groups and an average charge capacity A of the remaining battery groups excluding the any one battery group, based on the temperature of the area to which each battery group belongs, measured through the plurality of temperature sensors, during charging or discharging each battery group through the plurality of charging and discharging channels.

12. The controlling method of a charging and discharging apparatus according to claim 9, wherein the modified charge capacity of a battery cell among the battery groups is calculated using the following equation 2,
$$ACC = MCC \times \{ 1 + ( A - B ) / B \} \qquad [ Equation 2 ]$$
where ACC represents the modified charge capacity of the battery cell, MCC represents the calculated charge capacity of the battery cell, B represents the average charge capacity of any one battery group among the plurality of battery groups, and A represent the average charge capacity of the remaining battery groups excluding the any one battery group.

13. The controlling method of a charging and discharging apparatus according to claim 11, wherein the temperature of the area to which each battery group belongs is the average temperature in a predetermined measurement section during charging or discharging of the plurality of battery cells.
